(19) United States
(12) Patent Application Publication
(10) Pub. No.: US 2026/0047176 A1
(43) Pub. Date: Feb. 12, 2026

(54) SEMICONDUCTOR DEVICE AND METHOD OF FABRICATING THE SAME

(71) Applicant: WUHAN XINXIN SEMICONDUCTOR MANUFACTURING CO., LTD., Wuhan, Hubei (CN)

(72) Inventors: Peng ZHU, Wuhan (CN); Zilu YE, Wuhan (CN); Beibei SHENG, Wuhan (CN); Sheng HU, Wuhan (CN)

(21) Appl. No.: 19/229,328

(22) Filed: Jun. 5, 2025

(30) Foreign Application Priority Data
Aug. 6, 2024 (CN) 202411067581.0

(51) Int. Cl. H10D 80/20; H01L 23/00; H01L 23/522; H01L 23/528; H10D 1/00; H10D 1/68

(52) U.S. Cl. CPC H10D 80/215; H01L 23/5223; H01L 23/5286; H01L 24/08; H01L 24/80; H10D 1/042; H10D 1/716; H01L 2224/08145; H01L 2224/80006; H01L 2224/80895; H01L 2224/80896; H01L 2924/1205; H01L 2924/1431

(57) ABSTRACT

The present invention provides a semiconductor device and a method of fabricating the device, in which in each adjacent pair of semiconductor substrates, a first semiconductor substrate is bonded to a backside of a second semiconductor substrate, and external connection terminals are adjacent, and electrically connected, to a second semiconductor substrate. In each adjacent pair of semiconductor substrates, there is a first dielectric layer containing plug structures, which electrically connect the semiconductor substrates to each other. With this arrangement, power from an external power source can be supplied to each semiconductor substrate through a power transmission path constructed of plug structures. At least some first dielectric layers each contain a DTC structure, which is electrically connected to second ends of the plug structures in specific first dielectric layer. During propagation of an electrical signal through the plug structures, it passes through the DTC structure before arriving at downstream semiconductor substrate.

### CROSS-REFERENCES TO RELATED APPLICATION

This application claims the priority of Chinese patent application number 202411067581.0, filed on Aug. 6, 2024 and entitled “SEMICONDUCTOR DEVICE AND METHOD OF FABRICATING THE SAME”, the entire contents of which are incorporated herein by reference.

### TECHNICAL FIELD

The present invention relates to the field of semiconductor technology and, in particular, to a semiconductor device and a method of fabricating the same.

### BACKGROUND

As integration technology is advancing, stacked semiconductor devices (e.g., 3D integrated circuits) are finding increasingly wide use thanks to their advantages of small dimensions and excellent performance. In a stacked semiconductor device, various modules, such as logic circuit, memory and processing modules, are fabricated on separate semiconductor substrates, which are then stacked together and packaged so that each adjacent pair of semiconductor substrates is electrically connected by through silicon vias (TSVs). Conventional stacked semiconductor devices include three-dimensional (3D) dynamic random-access memory (DRAM) and other devices.

Since TSVs introduce parasitic inductance, more stacked semiconductor substrates mean a longer power transmission path constructed of more TSVs, which introduce more parasitic inductance. Consequently, the power transmission path will exhibit higher impedance, causing greater voltage drops along the path, which are detrimental to power integrity of the semiconductor substrates. In severe cases, it may be impossible to supply power to one or more of the semiconductor substrates.

### SUMMARY

It is an object of the present invention to overcome the problem that power consistency is not ensured for conventional stacked semiconductor devices by presenting a semiconductor device and a method of fabricating the device.

To this end, the present invention provides a semiconductor device including external connection terminals and at least two stacked semiconductor substrates each including power metal layers. In each adjacent pair of semiconductor substrates, a first semiconductor substrate is bonded to a backside of a second semiconductor substrate, and there is a first dielectric layer between the first and second semiconductor substrates. The external connection terminals are adjacent to a second semiconductor substrate and electrically connected to the power metal layers therein.

Each first dielectric layer contains plug structures, which also extend into the corresponding second semiconductor substrate, and first and second ends of which are electrically connected to the power metal layers in the corresponding first and second semiconductor substrates, respectively.

At least some of the first dielectric layer(s) each contain a deep trench capacitor (DTC) structure, which also extends into the corresponding second semiconductor substrate and is electrically connected to the second ends of the corresponding plug structures.

Optionally, the power metal layers in each semiconductor substrate may include a first power metal layer and a second power metal layer, and the plug structures in each first dielectric layer may include a first plug structure and a second plug structure, and
wherein a first end and a second end of the first plug structure are electrically connected to the corresponding first power metal layers, and a first end and a second end of the second plug structure are electrically connected to the corresponding second power metal layers.

Optionally, the DTC structure may include a first conductive layer and a second conductive layer, which are alternately stacked on top of each other, wherein each first conductive layer is separated from each adjacent second conductive layer by a dielectric material layer; and
each first conductive layer is electrically connected to the second end of the corresponding first plug structure, and each second conductive layer is electrically connected to the second end of the corresponding second plug structure.

Optionally, each first dielectric layer may further contain interconnect structures including a first interconnect structure and a second interconnect structure, wherein
the first interconnect structure electrically connects the corresponding first conductive layer to the second end of the corresponding first plug structure, and the second interconnect structure electrically connects the corresponding second conductive layer to the second end of the corresponding second plug structure.

Optionally, each first dielectric layer may include a first mask layer and a first dielectric sub-layer, which are stacked sequentially in the order on the backside of the corresponding second semiconductor substrate, wherein:
the plug structures are formed in the first dielectric sub-layer and extend through the first mask layer into the corresponding second semiconductor substrate; and
the DTC structure is formed between the first dielectric sub-layer and the first mask layer and extends through the first mask layer into the corresponding second semiconductor substrate.

Optionally, each first dielectric layer may include a second mask layer, a first mask layer and a second dielectric sub-layer, which are stacked sequentially in the order on the backside of the corresponding second semiconductor substrate, wherein:
the plug structures are formed in the second mask layer and extend through the second mask layer into the corresponding second semiconductor substrate; and
the DTC structure is formed between the second dielectric sub-layer and the first mask layer and extends through the first and second mask layers into the corresponding second semiconductor substrate.

Optionally, between each first dielectric layer and the corresponding first semiconductor substrate, there may also be a hybrid bonding structure including a first dielectric bond layer, a second dielectric bond layer, a first metal bond layer and a second metal bond layer,
the first dielectric bond layer attached to a surface of the specific first dielectric layer, the second dielectric bond layer attached to a front side of the first semiconductor substrate, the first metal bond layer embedded in the first dielectric bond layer and electrically connected to the plug structures in the specific first dielectric layer, the second metal bond layer embedded in the second dielectric bond layer and electrically connected to the power metal layers in the first semiconductor substrate,
a surface of the first metal bond layer at least partially exposed outside the first dielectric bond layer, a surface of the second metal bond layer at least partially exposed outside the second dielectric bond layer, surfaces of the first dielectric bond layer and the second dielectric bond layer attached to each other, the surfaces of the first metal bond layer and the second metal bond layer attached to each other, the first semiconductor substrate and the second semiconductor substrate are bonded to each other through the hybrid bonding structure.

Optionally, one of the semiconductor substrates may be a logic substrate, and each of the other semiconductor substrate(s) may be a device substrate, wherein the logic substrate is an outermost one of the semiconductor substrates.

Optionally, the first interconnect structure and the second interconnect structure each may include stacked multiple metal layers and a conductive plug connecting adjacent metal layers, and wherein the first interconnect structure and the second interconnect structure include conductive materials.

Optionally, the external connection terminals may include a first external connection terminal and a second external connection terminal, the first external connection terminal is electrically connected to the corresponding first power metal layer, and the second external connection terminal is electrically connected to the corresponding second power metal layer.

The present invention also provides a method of fabricating a semiconductor device, including:
providing at least two semiconductor substrates each including power metal layers; and
stacking all the semiconductor substrates together and forming external connection terminals, wherein in each adjacent pair of semiconductor substrates, a first semiconductor substrate is bonded to a backside of a second semiconductor substrate, and there is a first dielectric layer between the first and second semiconductor substrates; the external connection terminals are adjacent to a second semiconductor substrate and electrically connected to the power metal layers therein; each first dielectric layer contains plug structures, which also extend into the corresponding second semiconductor substrate, and first and second ends of which are electrically connected to the power metal layers in the corresponding first and second semiconductor substrates, respectively; and at least some of the first dielectric layer(s) each contain a deep trench capacitor (DTC) structure, which also extends into the corresponding second semiconductor substrate and is electrically connected to the second ends of the corresponding plug structures.

Optionally, all the semiconductor substrates may be stacked together in such a manner that, in each adjacent pair of semiconductor substrates, the first semiconductor substrate is stacked on the second semiconductor substrate by: forming the first dielectric layer, the plug structures, the DTC structure and a first hybrid bonding structure on the backside of the second semiconductor substrate and a second hybrid bonding structure on the front side of the first semiconductor substrate; and then bonding the front side of the first semiconductor substrate to the backside of the second semiconductor substrate through the first and second hybrid bonding structures, wherein
after all the semiconductor substrates are stacked together, the external connection terminals are formed on the front side of the initial second semiconductor substrate.

Alternatively, all the semiconductor substrates may be stacked together in such a manner that, in each adjacent pair of semiconductor substrates, the second semiconductor substrate is stacked on the first semiconductor substrate by: forming the first dielectric layer, the plug structures, the DTC structure and a first hybrid bonding structure on the backside of the second semiconductor substrate and a second hybrid bonding structure on the front side of the first semiconductor substrate; and then bonding the second semiconductor substrate to the first semiconductor substrate through the first and second hybrid bonding structures, wherein
after all the semiconductor substrates are stacked together, the external connection terminals are formed on the front side of the last second semiconductor substrate.

Optionally, the formation of the first dielectric layer, the plug structures and the DTC structure on the backside of the semiconductor substrate may include:
forming a first mask layer on the backside of the semiconductor substrate and performing a local etching process, which proceeds through the first mask layer and a partial thickness of the semiconductor substrate, forming at least one deep trench;
forming the DTC structure on the first mask layer, which covers a surface portion of the first mask layer and extends into the deep trench;
forming a first dielectric sub-layer over the first mask layer and the DTC structure and performing a local etching process, which proceeds the first dielectric sub-layer, the first mask layer and a partial thickness of the semiconductor substrate, forming via holes exposing the power metal layers;
filling a conductive material into the via holes, forming the plug structures; and
forming a second dielectric sub-layer on the first dielectric sub-layer so that the first mask layer, the first dielectric sub-layer and the second dielectric sub-layer together constitute the first dielectric layer.

Alternatively, the formation of the first dielectric layer, the plug structures and the DTC structure on the backside of the semiconductor substrate may include:
forming a second mask layer on the backside of the semiconductor substrate and performing a local etching process, which proceeds through the second mask layer and a partial thickness of the semiconductor substrate, forming via holes exposing the power metal layers;
filling a conductive material into the via holes, forming the plug structures;
forming a first mask layer on the second mask layer and performing a local etching process, which proceeds the first mask layer, the second mask layer and a partial thickness of the semiconductor substrate, forming at least one deep trench;
forming the DTC structure on the first mask layer, which covers a surface portion of the first mask layer and extends into the deep trench; and
forming a second dielectric sub-layer over the first mask layer and the DTC structure so that the first mask layer, the second mask layer and the second dielectric sub-layer together constitute the first dielectric layer.

Optionally, during the formation of the first dielectric layer, interconnect structures may also be formed in the first dielectric layer, which are electrically connected to the second ends of the plug structures and the DTC structure.

Optionally, the formation of the first hybrid bonding structure on the first dielectric layer may include:
forming a first dielectric bond layer on the first dielectric layer; and
forming a first metal bond layer in the first dielectric bond layer, which is electrically connected to the plug structures by the interconnect structures, and a surface of which is at least partially exposed outside the first dielectric bond layer, and wherein
the formation of the second hybrid bonding structure on the front side of the semiconductor substrate includes:
forming a second dielectric bond layer on the front side of the semiconductor substrate; and
forming a second metal bond layer in the second dielectric bond layer, which is electrically connected to the power metal layers in the semiconductor substrate, and a surface of which is at least partially exposed outside the second dielectric bond layer.

The present invention provides a semiconductor device including external connection terminals and at least two stacked semiconductor substrates. In each adjacent pair of semiconductor substrates, a first semiconductor substrate is bonded to a backside of a second semiconductor substrate. The external connection terminals are electrically connected to an adjacent second semiconductor substrate. In each adjacent pair of semiconductor substrates, the two semiconductor substrates are electrically connected to each other by plug structures contained in a first dielectric layer between the two semiconductor substrates. When the external connection terminals are connected to an external power source, the latter can supply power to each semiconductor substrate through a power transmission path constructed of the plug structures. At least some of the first dielectric layer(s) each contain a DTC structure electrically connected to second ends of the plug structures in the specific first dielectric layer. During propagation of an electrical signal through the plug structures, it passes through the DTC structure before arriving at the downstream semiconductor substrate. The DTC structure can filter out any parasitic inductance that the plug structures introduce, facilitating powering of the downstream semiconductor substrate. With this arrangement, the power transmission path has lower impedance, and reduced voltage drops occur along the path, allowing more chips/wafers to be stacked together. Also provided is a method of fabricating the semiconductor device.

### BRIEF DESCRIPTION OF THE DRAWINGS

FIG. 1 shows a flowchart of a method of fabricating a semiconductor device according to a first embodiment of the present invention.

FIGS. 2 to 14 schematically illustrate structures resulting from respective steps in the method according to the first embodiment of the present invention, in which: FIG. 2 is a schematic diagram showing the structure of a second semiconductor substrate according to the first embodiment of the present invention; FIG. 3 schematically depicts a structure resulting from bonding a support substrate to a front side of the second semiconductor substrate according to the first embodiment of the present invention; FIG. 4 schematically depicts a structure resulting from forming a first mask layer on a backside of the second semiconductor substrate and a deep trench therein according to the first embodiment of the present invention; FIG. 5 schematically depicts a structure resulting from conformally forming an isolation layer over the first mask layer according to the first embodiment of the present invention; FIG. 6 schematically depicts a structure resulting from forming a deep trench capacitor (DTC) structure in the deep trench according to the first embodiment of the present invention; FIG. 7 schematically depicts a structure resulting from forming a first dielectric sub-layer over the isolation layer and the DTC structure and then first and second via holes according to the first embodiment of the present invention; FIG. 8 schematically depicts a structure resulting from forming first and second plug structures in the first and second via holes according to the first embodiment of the present invention; FIG. 9 schematically depicts a structure resulting from forming a second dielectric sub-layer on the first dielectric sub-layer according to the first embodiment of the present invention; FIG. 10 schematically depicts a structure resulting from forming a first hybrid bonding structure on the second dielectric sub-layer according to the first embodiment of the present invention; FIG. 11 schematically depicts a structure resulting from forming a first hybrid bonding structure on a front side of a first semiconductor substrate according to the first embodiment of the present invention; FIG. 12 schematically depicts a structure resulting from bonding the front side of the first semiconductor substrate to the backside of the second semiconductor substrate according to the first embodiment of the present invention; FIG. 13 schematically depicts a stack of a desired number of semiconductor substrates according to the first embodiment of the present invention; and FIG. 14 is a schematic diagram showing the structure of a semiconductor device according to the first embodiment of the present invention.

FIG. 15 shows an equivalent wiring diagram of the semiconductor device according to the first embodiment of the present invention.

FIGS. 16 to 24 schematically depict structures resulting from respective steps in a method of fabricating a semiconductor device according to a second embodiment of the present invention, in which: FIG. 16 schematically depicts a structure resulting from forming a second mask layer on a backside of a second semiconductor substrate and then first and second via holes according to the second embodiment of the present invention; FIG. 17 schematically depicts a structure resulting from forming first and second plug structures in the first and second via holes according to the second embodiment of the present invention; FIG. 18 schematically depicts a structure resulting from forming a first mask layer on the second mask layer and then a deep trench according to the second embodiment of the present invention; FIG. 19 schematically depicts a structure resulting from forming an isolation layer over the first mask layer according to the second embodiment of the present invention; FIG. 20 schematically depicts a structure resulting from forming a DTC structure in the deep trench according to the second embodiment of the present invention; FIG. 21 schematically depicts a structure resulting from forming a second dielectric sub-layer over the isolation layer and the DTC structure according to the second embodiment of the present invention; FIG. 22 schematically depicts a structure resulting from forming a first hybrid bonding structure on the second dielectric sub-layer according to the second embodiment of the present invention; FIG. 23 schematically depicts a structure resulting from bonding a front side of a first semiconductor substrate to the backside of the second semiconductor substrate according to the second embodiment of the present invention; and FIG. 24 is a schematic diagram showing the structure of a semiconductor device according to the second embodiment of the present invention.

FIGS. 25 to 28 schematically depict structures resulting from respective steps in a method of fabricating a semiconductor device according to a third embodiment of the present invention, in which: FIG. 25 schematically depicts a structure resulting from bonding a backside of a second semiconductor substrate to a front side of a first semiconductor substrate according to the third embodiment of the present invention; FIG. 26 schematically depicts a structure resulting from removing a support substrate and forming a second hybrid bonding structure on the front side of the first semiconductor substrate according to the third embodiment of the present invention; FIG. 27 schematically depicts a structure resulting from bonding a backside of another second semiconductor substrate to the front side of the first semiconductor substrate according to the third embodiment of the present invention; and FIG. 28 is a schematic diagram showing the structure of a semiconductor device according to the third embodiment of the present invention.

### LIST OF REFERENCE NUMERALS

100 semiconductor substrate; 101a first power metal layer; 101b second power metal layer; 102 deep trench; 200 support substrate; 300 temporary bond layer; 401 first mask layer; 402 isolation layer; 403 second mask layer; 500 DTC structure; 501 first conductive layer; 502 second conductive layer; 503 dielectric material layer; 601 first dielectric sub-layer; 601a first via hole; 601b second via hole; 602 second dielectric sub-layer; 701a first interconnect structure; 701b second interconnect structure; 702a first plug structure; 702b second plug structure; 801a first metal bond sub-layer; 801b second metal bond sub-layer; 802 first dielectric bond layer; 803 second dielectric bond layer; 804a third metal bond sub-layer; 804b fourth metal bond sub-layer; 805 second dielectric layer; 806a first external connection terminal; 806b second external connection terminal.

### DETAILED DESCRIPTION

The present invention will be described in greater detail below with reference to the accompanying drawings, which illustrate particular embodiments thereof. From the following description, advantages and features of the present invention will be more apparent. Note that the figure is provided in a very simplified form not necessarily drawn to exact scale for the only purpose of helping to explain the disclosed embodiments in a more convenient and clearer way.

### Example 1

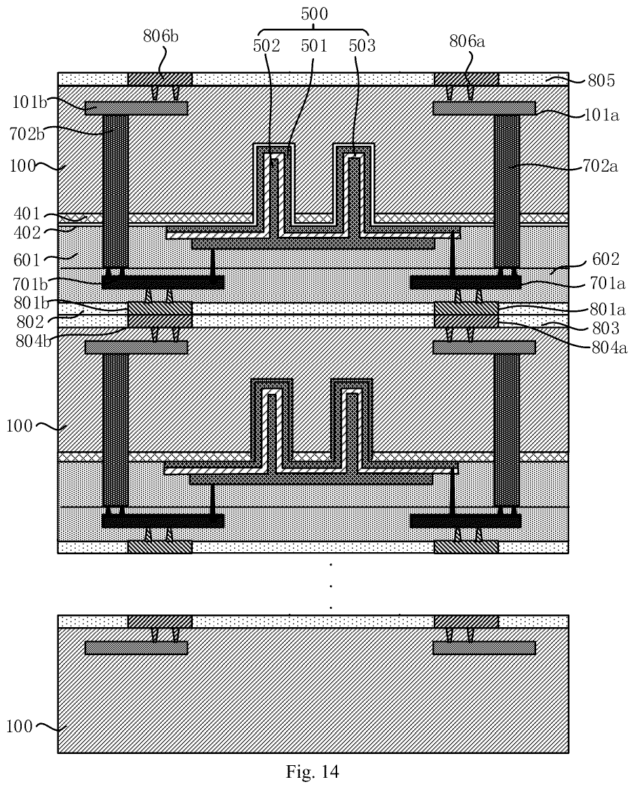

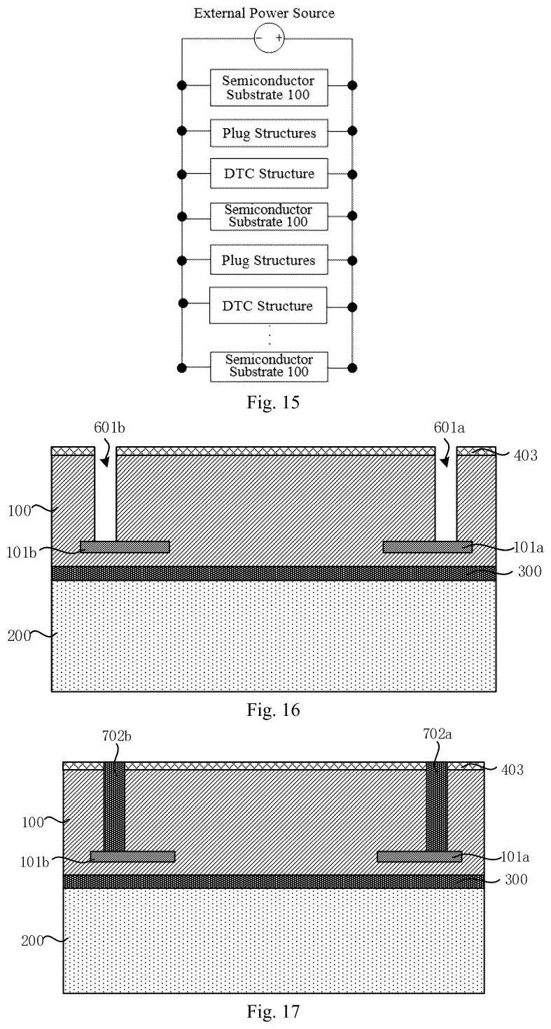

FIG. 14 shows a schematic diagram showing the structure of a semiconductor device according to a first embodiment of the present invention. As shown in FIG. 14, in this embodiment, the semiconductor device includes at least two stacked semiconductor substrates 100. FIG. 14 schematically depicts three semiconductor substrates 100, and all other possible semiconductor substrates 100 are indicated by the ellipsis in the figure.

Each semiconductor substrate 100 includes a substrate and an insulating layer on a first surface of the substrate (both not labeled with reference numerals in FIG. 14). A device structure may be formed on the first surface of the substrate, which may be an active device (e.g., a transistor, a diode, a triode, etc.), a passive device (e.g., a capacitor, a resistor, an inductor, etc.) or a combination thereof. The insulating layer contains power metal layers electrically connected to the device structure. The power metal layers include a first power metal layer 101a and a second power metal layer 101b, which are electrically connected to the device structure in the semiconductor substrate 100 to allow power to be supplied thereto. The semiconductor device may be a stacked semiconductor device, such as a three-dimensional (3D) dynamic random-access memory (DRAM) device.

The substrate may be formed of a semiconductor material, glass, ceramic or other material. Examples of the semiconductor material may include, but are not limited to, doped or undoped silicon (Si), doped or undoped germanium (Ge), semiconductor on insulator (SOI), silicon carbide (SiC), gallium arsenide (GaAs), gallium phosphide (GaP), indium phosphide (InP), indium arsenide (InAs) and/or indium antimonide (InSb), SiGe, GaAsP, AlInAs, AlGaAs, GaInAs, GaInP and/or GaInAsP and combinations thereof. The semiconductor substrate 100 may have a size comparable to that of a wafer or chip. For example, the semiconductor substrate 100 may be a wafer or chip, such as an optoelectronic wafer/chip, a bio-wafer/chip, a memory wafer/chip, a logic wafer/chip, a computing wafer/chip, etc. For example, in this embodiment, the stack may be a combination of a single logic chip and multiple memory chips.

The insulating layer may include a single or multiple films. Examples of a material from which the insulating layer can be fabricated may include, but are not limited to, low-k dielectric materials, phosphosilicate glass (PSG), borosilicate glass (BSG), borophosphosilicate glass (BPSG), undoped silicate glass (USG), silicon oxide, silicon nitride, silicon oxynitride, silicon carbide, carbon-doped silicon dioxide, etc.

In this embodiment, the semiconductor substrate 100 has a front side provided by the insulating layer (more precisely, by the exposed side of the insulating layer) and a backside provided by the substrate (more precisely, by a second surface of the substrate). Each adjacent pair of the semiconductor substrates 100 is stacked so that a first semiconductor substrate 100 is bonded to the backside of a second semiconductor substrate 100. More precisely, the front side of the first semiconductor substrate 100 is bonded to the backside of the second semiconductor substrate 100.

It should be noted that, herein, in each adjacent pair of semiconductor substrates 100, one of the semiconductor substrates 100 may be referred to as a “first semiconductor substrate 100” and the other as a “second semiconductor substrate 100”. For example, the semiconductor substrates 100 may be numbered from the top downwards as No. 1 semiconductor substrate 100, No. 2 semiconductor substrate 100, No. 3 semiconductor substrate 100, . . . , No. n semiconductor substrate 100. No. 1 semiconductor substrate 100 is adjacent to No. 2 semiconductor substrate 100; No. 2 semiconductor substrate 100 is adjacent to No. 3 semiconductor substrate 100; and so forth. Regarding Nos. 1 and 2 semiconductor substrates 100, No. 2 semiconductor substrate 100 may be referred to a “first semiconductor substrate 100” and No. 1 semiconductor substrate 100 as a “second semiconductor substrate 100”. Likewise, Regarding Nos. 2 and 3 semiconductor substrates 100, No. 3 semiconductor substrate 100 may be referred to a “first semiconductor substrate 100” and No. 2 semiconductor substrate 100 as a “second semiconductor substrate 100”. The same applies to all the other adjacent pairs.

It will be understood that, after all the semiconductor substrates 100 are stacked together, in the two outermost semiconductor substrates 100, one of them is a first semiconductor substrate 100 (with its backside facing the outside), and the other is a second semiconductor substrate 100 (with its front side facing the outside).

The semiconductor device further includes a second dielectric layer 805 and external connection terminals contained in the second dielectric layer 805. As the most external component of the semiconductor device, the second dielectric layer 805 covers the front side of the adjacent second semiconductor substrate 100 (i.e., the second one of the outermost semiconductor substrates 100). The external connection terminals include a first external connection terminal 806a and a second external connection terminal 806b. The first external connection terminal 806a is electrically connected to the corresponding first power metal layer 101a, and the second external connection terminal 806b is electrically connected to the corresponding second power metal layer 101b.

Additionally, a first dielectric layer is sandwiched between the two semiconductor substrates 100 in each adjacent pair of semiconductor substrates 100, more precisely, between the front side of the first semiconductor substrate 100 and the backside of the second semiconductor substrate 100. The first dielectric layer may include a single or multiple films. Examples of a material from which the first dielectric layer can be fabricated may include, but are not limited to, low-k dielectric materials, PSG, BSG, BPSG, USG, silicon oxide, silicon nitride, silicon oxynitride, silicon carbide, carbon-doped silicon dioxide and so on.

Each first dielectric layer contains plug structures, which extend into the corresponding second semiconductor substrate 100. First and second ends of the plug structures are electrically connected to the power metal layers in the first and second semiconductor substrates 100, respectively. Specifically, the plug structures include a first plug structure 702a and second plug structure 702b. First and second ends of the first plug structure 702a are electrically connected to the corresponding first power metal layers 101a, and first and second ends of the second plug structure 702b are electrically connected to the corresponding second power metal layers 101b.

Further, at least some of the first dielectric layer(s) each contain a deep trench capacitor (DTC) structure 500, the DTC structure 500 extends into the corresponding second semiconductor substrate 100, and the DTC structure 500 is electrically connected to the second ends of the corresponding plug structures. In this embodiment, each first dielectric layer contains the DTC structure 500. In some other embodiments, only some of the first dielectric layer(s) each contain a DTC structure 500.

Specifically, the DTC structure 500 includes a first conductive layer 501 stacked with a second conductive layer 502. The first conductive layer 501 is separated from the second conductive layer 502 by a dielectric material layer 503. The first conductive layer 501 is closer to the second semiconductor substrate 100 than the second conductive layer 502. The first conductive layer 501 is electrically connected to the second end of the corresponding first plug structure 702a, and the second conductive layer 502 is electrically connected to the second end of the corresponding second plug structure 702b. Thus, the DTC structure 500 is connected in parallel to the plug structures.

In this embodiment, the DTC structure 500 includes a single first conductive layer 501, a single second conductive layer 502 and a single dielectric material layer 503. In alternative embodiments, the DTC structure 500 may include alternately stacked multiple first and second conductive layers 501 and 502, wherein each first conductive layer 501 is separated from each adjacent second conductive layer 502 by a dielectric material layer 503.

Further, each first dielectric layer also contains interconnect structures, which include a first interconnect structure 701a and a second interconnect structure 701b. The first interconnect structure 701a electrically connects the first conductive layer 501 to the second end of the corresponding first plug structure 702a, and the second interconnect structure 701b electrically connects the second conductive layer 502 to the second end of the corresponding second plug structure 702b.

Specifically, the first dielectric layer includes a first mask layer 401, an isolation layer 402, a first dielectric sub-layer 601 and a second dielectric sub-layer 602, which are stacked on the backside of the corresponding second semiconductor substrate 100 sequentially in this order. The first plug structure 702a and the second plug structure 702b are partially embedded in the first dielectric sub-layer 601 and extend through the isolation layer 402 and the first mask layer 401 into the corresponding second semiconductor substrate 100. The first plug structure 702a and the second plug structure 702b are also electrically connected to the first power metal layer 101a and the second power metal layer 101b in the second semiconductor substrate 100.

The DTC structure 500 is situated between the isolation layer 402 and the first dielectric sub-layer 601 and extends through the first mask layer 401 into the second semiconductor substrate 100. The isolation layer 402 wraps the portion of the DTC structure 500 in the second semiconductor substrate 100. The first interconnect structure 701a and the second interconnect structure 701b are situated in the second dielectric sub-layer 602. The first interconnect structure 701a is electrically connected to the second end of the first plug structure 702a and the first conductive layer 501. The second interconnect structure 701b is electrically connected to the second end of the second plug structure 702b and the second conductive layer 502.

Optionally, the first interconnect structure 701a and the second interconnect structure 701b may each include stacked multiple metal layers and a conductive plug connecting adjacent metal layers. The first interconnect structure 701a and the second interconnect structure 701b may include conductive materials, such as tungsten, cobalt, nickel, copper, silver, gold, aluminum or a combination thereof.

Additionally, there is a hybrid bonding structure between each second dielectric sub-layer 602 and the front side of the corresponding first semiconductor substrate 100. The hybrid bonding structure includes a first dielectric bond layer 802, a second dielectric bond layer 803, a first metal bond layer and a second metal bond layer. The first dielectric bond layer 802 is attached to a surface of the second dielectric sub-layer 602, and the second dielectric bond layer 803 is attached to the front side of the first semiconductor substrate 100.

The first metal bond layer is embedded in the first dielectric bond layer 802 and includes a first metal bond sub-layer 801a and a second metal bond sub-layer 801b. The first metal bond sub-layer 801a is electrically connected to the corresponding first interconnect structure 701a and hence to the corresponding first plug structure 702a. The second metal bond sub-layer 801b is electrically connected to the corresponding second interconnect structure 701b and hence to the corresponding second plug structure 702b. The second metal bond layer is embedded in the second dielectric bond layer 803 and includes a third metal bond sub-layer 804a and a fourth metal bond sub-layer 804b. The third metal bond sub-layer 804a is electrically connected to the first power metal layer 101a in the corresponding first semiconductor substrate 100, and the fourth metal bond sub-layer 804b is electrically connected to the second power metal layer 101b in the corresponding first semiconductor substrate 100.

Surfaces of the first metal bond sub-layer 801a and the second metal bond sub-layer 801b are at least partially exposed from the first dielectric bond layer 802, and surfaces of the third metal bond sub-layer 804a and the fourth metal bond sub-layer 804b are at least partially exposed from the second dielectric bond layer 803. The first dielectric bond layer 802 and the second dielectric bond layer 803 are surface-bonded to each other. The first metal bond sub-layer 801a and the third metal bond sub-layer 804a are surface-bonded to each other. The second metal bond sub-layer 801b and the fourth metal bond sub-layer 804b are surface-bonded to each other. In this way, the first semiconductor substrate 100 and the second semiconductor substrate 100 are bonded together by the hybrid bonding structure.

FIG. 15 shows an equivalent wiring diagram of the semiconductor device of the present embodiment. As shown in FIG. 15, an electrical signal is input to the semiconductor device from an external power source through the external connection terminals. The second semiconductor substrate 100 adjacent to the external connection terminals is directly powered by the electrical signal input through the external connection terminals. The electrical signal then passes to the downstream semiconductor substrate 100 through the plug structures and the DTC structure 500. The DTC structure 500 filters out any parasitic inductance that the plug structures introduce, facilitating powering of the downstream semiconductor substrate 100. With this arrangement, the power transmission path has lower impedance, and reduced voltage drops occur along the path, allowing more chips/wafers to be stacked together.

It should be noted that, in some embodiments, one of the semiconductor substrates 100 in the semiconductor device may be a logic substrate (e.g., a logic wafer or chip), and the other semiconductor substrate(s) 100 may each be a device substrate (e.g., a device wafer or chip). The logic substrate is an outermost one of the semiconductor substrates 100. In this embodiment, the logic substrate is the semiconductor substrate 100 adjacent to the external connection terminals. However, the present invention is not so limited.

On this basis, in the present embodiment, there is also provided a method of fabricating a semiconductor device. FIG. 1 shows a flowchart of this method. As shown in FIG. 1, the method includes the steps of:
S1) providing at least two semiconductor substrates each containing power metal layers; and
S2) stacking all the semiconductor substrates together and forming external connection terminals. In each adjacent pair of semiconductor substrates, a first semiconductor substrate is bonded to a backside of a second semiconductor substrate, and there is a first dielectric layer between the first and second semiconductor substrates. The external connection terminals are electrically connected to the power metal layers in the adjacent second semiconductor substrate. Each first dielectric layer contains plug structures, which also extend into the corresponding second semiconductor substrate. First and second ends of the plug structures are electrically connected to the power metal layers in the corresponding first and second semiconductor substrates, respectively. At least some of the first dielectric layer(s) each contain a DTC structure, which also extends into the corresponding second semiconductor substrate and is electrically connected to the second ends of the corresponding plug structures.

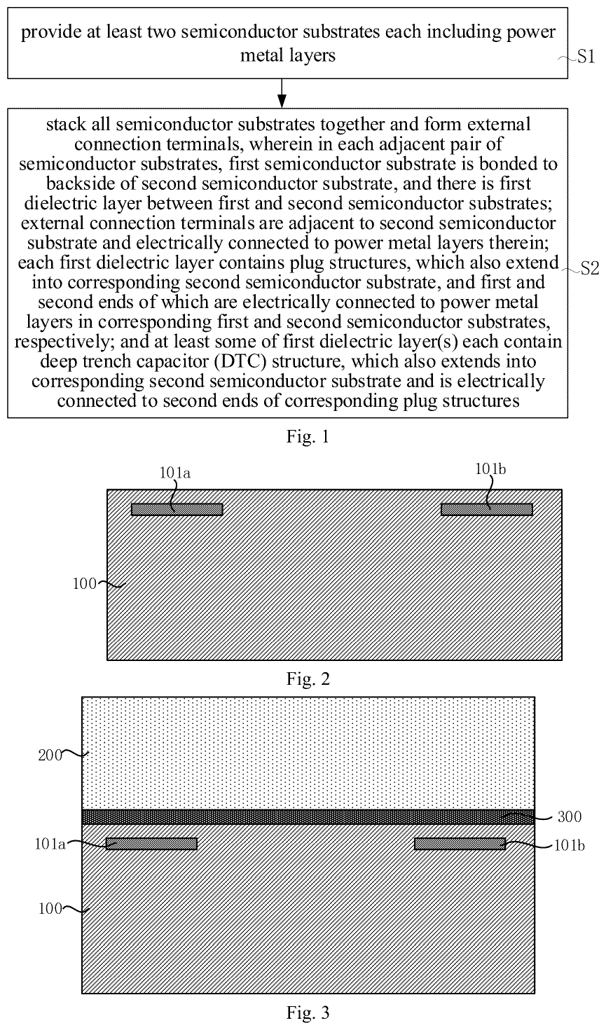

FIGS. 2 to 14 are schematic diagrams showing structures resulting from respective steps in the method of the present embodiment. The method of this embodiment is described in greater detail below with reference to FIGS. 2 to 14.

In step S1, as shown in FIG. 2, at least two semiconductor substrates 100 are provided, each including a substrate, an insulating layer and a first power metal layer 101a and a second power metal layer 101b both contained in the insulating layer (the substrate and the insulating layer are not labeled with reference numeral in FIG. 2). Each semiconductor substrate 10 has a front side and a backside.

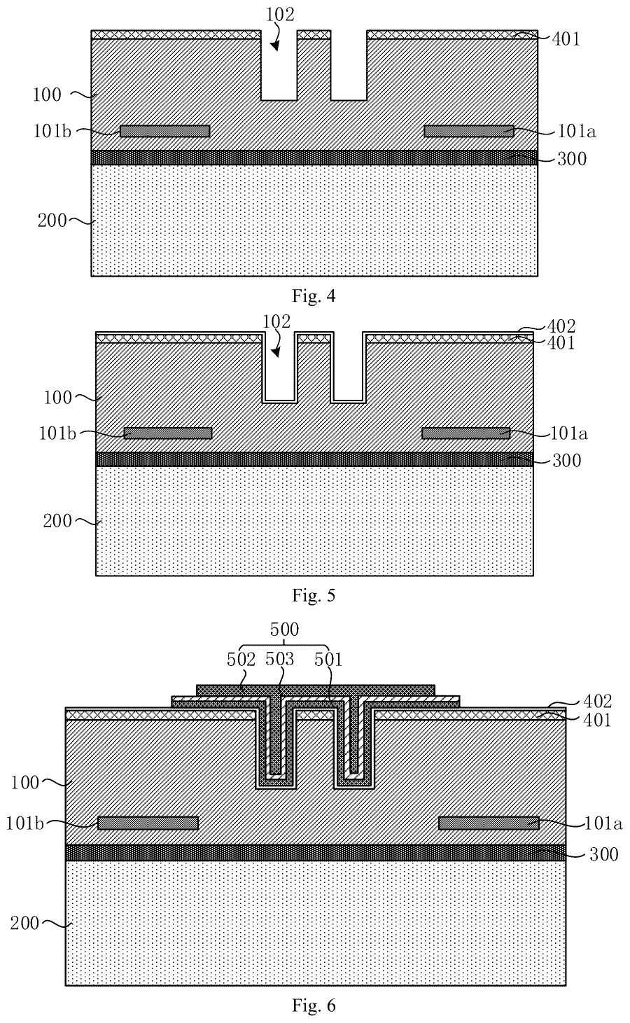

In step S2, as shown in FIG. 3, a second semiconductor substrate 100 is processed. Specifically, a support substrate 200 is bonded to the front side of the second semiconductor substrate 100. The support substrate 200 may not contain any functional component. Alternatively, the support substrate 200 may contain one or more functional components. In some embodiments, the functional component(s) may be contained within the support substrate 200 and/or along an edge and/or on a surface thereof.

In this embodiment, a temporary bond layer 300 may be formed on the support substrate 200, and the support substrate 200 may be bonded to the second semiconductor substrate 100 through the temporary bond layer 300. Examples of a method used to bond the support substrate 200 to the second semiconductor substrate 100 may include, fusion bonding, thermo-compression bonding, low-temperature vacuum bonding, anodic bonding, eutectic bonding and hybrid bonding.

As shown in FIG. 4, the second semiconductor substrate 100 is polished and thinned from the backside, and a first mask layer 401 is formed on the backside of the second semiconductor substrate 100. The first mask layer 401 completely covers the backside of the second semiconductor substrate 100. Subsequently, a local etching process is carried out, which proceeds through the first mask layer 401 into the second semiconductor substrate 100, forming at least one deep trench 102 extending through the first mask layer 401 and a partial thickness of the underlying second semiconductor substrate 100.

As shown in FIG. 5, an isolation layer 402 is conformally formed over the first mask layer 401. The isolation layer 402 further extends into and lines the deep trench 102.

As shown in FIG. 6, a first conductive layer 501, a dielectric material layer 503 and a second conductive layer 502 are successively formed on a surface portion of the isolation layer 402. The first conductive layer 501, the second conductive layer 502 and the dielectric material layer 503 all extend into and together fill the deep trench 102, thus forming a DTC structure 500. In this embodiment, the first conductive layer 501 and the dielectric material layer 503 both cover the surface portion of the isolation layer 402, and the second conductive layer 502 covers a surface portion of the dielectric material layer 503. The DTC structure 500 is electrically isolated from the second semiconductor substrate 100 by the isolation layer 402.

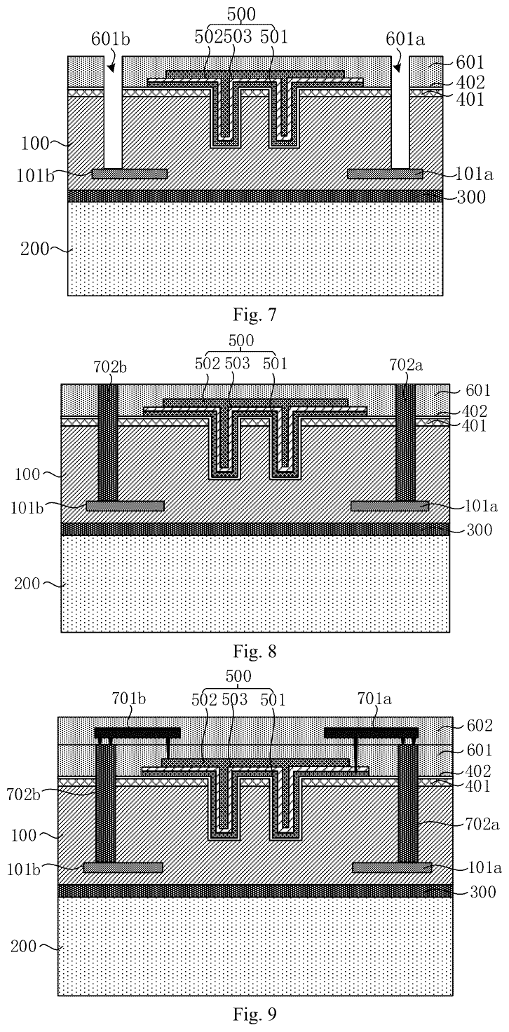

As shown in FIG. 7, a first dielectric sub-layer 601 is formed over the isolation layer 402 and the DTC structure 500. The first dielectric sub-layer 601 covers the isolation layer 402 and the DTC structure 500. A local etching process is then performed, which proceeds through the first dielectric sub-layer 601, the isolation layer 402, the first mask layer 401 and a partial thickness of the second semiconductor substrate 100 until the first power metal layer 101a and the second power metal layer 101b are exposed, forming a first via hole 601a and a second via hole 601b. The first via hole 601a extends through the first dielectric sub-layer 601, the isolation layer 402 and the first mask layer 401 into the second semiconductor substrate 100, exposing the first power metal layer 101a. The second via hole 601b extends through the first dielectric sub-layer 601, the isolation layer 402 and the first mask layer 401 into the second semiconductor substrate 100, exposing the second power metal layer 101b.

As shown in FIG. 8, a conductive material is filled in the first via hole 601a and the second via hole 601b, forming a first plug structure 702a and a second plug structure 702b. In FIG. 8, each of the first plug structure 702a and the second plug structure 702b has a first end embedded in the second semiconductor substrate 100 and a second end opposing the first end.

As shown in FIG. 9, a second dielectric sub-layer 602 is formed on the first dielectric sub-layer 601, and a first interconnect structure 701a and a second interconnect structure 701b in the second dielectric sub-layer 602. The first interconnect structure 701a resides on top of the first plug structure 702a and is electrically connected to the second end of the first plug structure 702a and the first conductive layer 501. The second interconnect structure 701b resides on top of the second plug structure 702b and is electrically connected to the second end of the second plug structure 702b and the second conductive layer 502. The isolation layer 402, the first mask layer 401, the first dielectric sub-layer 601 and the second dielectric sub-layer 602 together constitute a first dielectric layer.

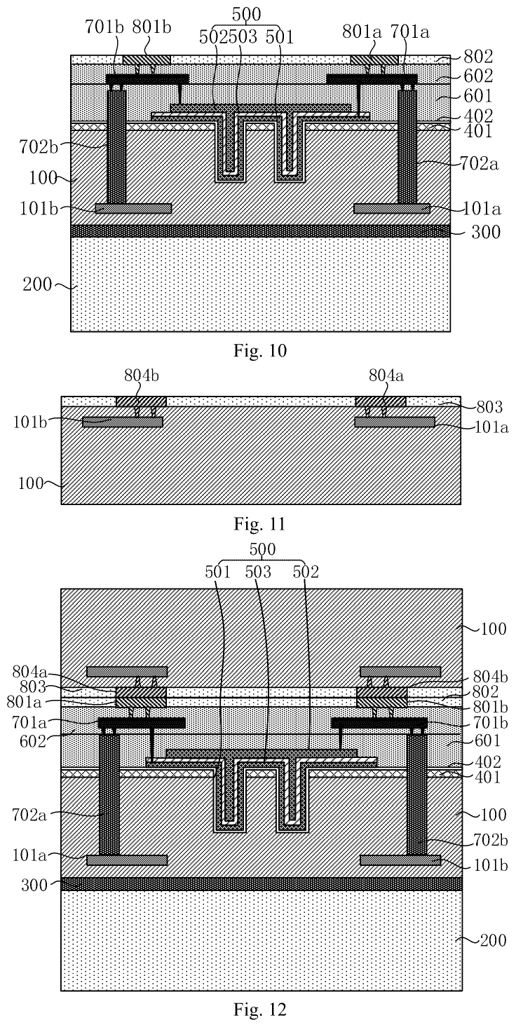

As shown in FIG. 10, a first dielectric bond layer 802 is formed on the second dielectric sub-layer 602. The first dielectric bond layer 802 covers the second dielectric sub-layer 602. A first metal bond layer is then formed in the first dielectric bond layer 802, which includes a first metal bond sub-layer 801a and a second metal bond sub-layer 801b. The first metal bond sub-layer 801a also extends into the second dielectric sub-layer 602 and is electrically connected to the first interconnect structure 701a. The second metal bond sub-layer 801b also extends into the second dielectric sub-layer 602 and is electrically connected to the second interconnect structure 701b. Surfaces of the first metal bond sub-layer 801a and the second metal bond sub-layer 801b are at least partially exposed outside the first dielectric bond layer 802. The first dielectric bond layer 802 and the first metal bond layer together constitute a first hybrid bonding structure.

As shown in FIG. 11, a first semiconductor substrate 100 is processed. Specifically, a second dielectric bond layer 803 is formed on the front side of the first semiconductor substrate 100. The second dielectric bond layer 803 covers the front side of the first semiconductor substrate 100. A second metal bond layer is then formed in the second dielectric bond layer 803, which includes a third metal bond sub-layer 804a and a fourth metal bond sub-layer 804b. The third metal bond sub-layer 804a also extends into the first semiconductor substrate 100 and is electrically connected to the first power metal layer 101a therein. The fourth metal bond sub-layer 804b also extends into the first semiconductor substrate 100 and is electrically connected to the second power metal layer 101b therein. Surfaces of the third metal bond sub-layer 804a and the fourth metal bond sub-layer 804b are at least partially exposed outside the second dielectric bond layer 803. The second dielectric bond layer 803 and the second metal bond layer together constitute a second hybrid bonding structure.

It should be noted that the first semiconductor substrate 100 may also be processed at a different time, for example, before or during the processing of the second semiconductor substrate 100.

Referring to FIG. 12, the first hybrid bonding structure is boned to the second hybrid bonding structure so that surfaces of the first dielectric bond layer 802 and the second dielectric bond layer 803 are tightly attached to each other, the surfaces of the first metal bond sub-layer 801a and the third metal bond sub-layer 804a attached to each other and the surfaces of the second metal bond sub-layer 801b and the fourth metal bond sub-layer 804b attached to each other. As a result, the front side of the first semiconductor substrate 100 is bonded to the backside of the second semiconductor substrate 100 by dielectric-to-dielectric adhesion and metal-to-metal adhesion.

As a result of the above steps, the two semiconductor substrates 100 are stacked together.

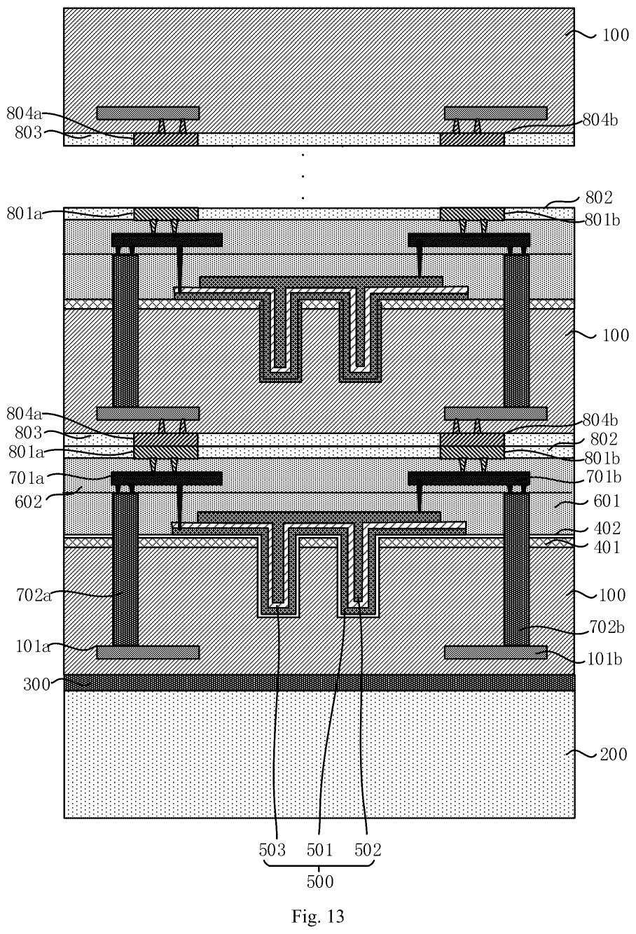

Next, as shown in FIG. 13, with the first semiconductor substrate 100 of FIG. 12 being now taken as a new second semiconductor substrate 100 and another semiconductor substrate 100 as a new first semiconductor substrate 100, the above steps are repeated to further stack the other semiconductor substrate 100. In this way, new first semiconductor substrates 100 can be successively stacked on respective second semiconductor substrates 100. In each adjacent pair of semiconductor substrates 100, the stacking of the first semiconductor substrate 100 on the second semiconductor substrate 100 involves: first forming a first dielectric layer, plug structures, a DTC structure 500 and a first hybrid bonding structure on the backside of the second semiconductor substrate 100; then forming a second hybrid bonding structure on the front side of the first semiconductor substrate 100; and finally bonding the front side of the first semiconductor substrate 100 to the backside of the second semiconductor substrate 100 through the first and second hybrid bonding structures. As such, a desired number of semiconductor substrates 100 can be stacked together.

As shown in FIG. 14, after all the semiconductor substrates 100 are stacked together, the support substrate 200 may be debonded and then removed together with the temporary bond layer 300. After that, a second dielectric layer 805 may be formed on the initial second semiconductor substrate 100, and a first external connection terminal 806a and a second external connection terminal 806b in the second dielectric layer 805. The first external connection terminal 806a and the second external connection terminal 806b may also extend into the initial second semiconductor substrate 100 and be electrically connected to the first power metal layer 101a and the second power metal layer 101b therein, respectively. The first external connection terminal 806a and the second external connection terminal 806b serve for external connection.

### Example 2

FIG. 24 is a schematic diagram showing the structure of a semiconductor device according to a second embodiment of the present invention. As shown in FIG. 24, it differs from the first embodiment in that each first dielectric layer includes a second mask layer 403, a first mask layer 401, an isolation layer 402 and a second dielectric sub-layer 602, which are sequentially stacked on the backside of a corresponding second semiconductor substrate 100. The second mask layer 403 contains a first plug structure 702a and a second plug structure 702b, which extend through the second mask layer 403 into the second semiconductor substrate 100 and are electrically connected to the first power metal layer 101a and the second power metal layer 101b in the second semiconductor substrate 100, respectively. Situated between the isolation layer 402 and the second dielectric sub-layer 602 is a DTC structure 500, which extends through the first mask layer 401 and the second mask layer 403 into the second semiconductor substrate 100. The isolation layer 402 wraps the portion of the DTC structure 500 in the second semiconductor substrate 100.

It will be understood that the first plug structure 702a and the second plug structure 702b of this embodiment are shorter than those of the first embodiment and can be more easily fabricated. Additionally, the DTC structure 500 is taller (due to the presence of the second mask layer 403), and hence an increased area and higher capacitance density.

FIGS. 16 to 24 are schematic diagrams showing structures resulting from respective steps in the method of the present embodiment. The method of this embodiment is described in greater detail below with reference to FIGS. 16 to 24.

Similar to the first embodiment, a support substrate 200 is first bonded to the front side of a second semiconductor substrate 100. As shown in FIG. 16, the second semiconductor substrate 100 is polished and thinned from the backside, and a second mask layer 403 is formed on the backside of the second semiconductor substrate 100. The second mask layer 403 completely covers the backside of the second semiconductor substrate 100. Subsequently, a local etching process is carried out, which proceeds through the second mask layer 403 into the second semiconductor substrate 100 until the first power metal layer 101a and the second power metal layer 101b are exposed, forming a first via hole 601a and a second via hole 601b. The first via hole 601a extends through the second mask layer 403 into the second semiconductor substrate 100, exposing the first power metal layer 101a. The second via hole 601b extends through the second mask layer 403 into the second semiconductor substrate 100, exposing the second power metal layer 101b.

As shown in FIG. 17, a conductive material is filled in the first via hole 601a and the second via hole 601b, forming a first plug structure 702a and a second plug structure 702b. In FIG. 17, each of the first plug structure 702a and the second plug structure 702b has a first end embedded in the second semiconductor substrate 100 and a second end opposing the first end.

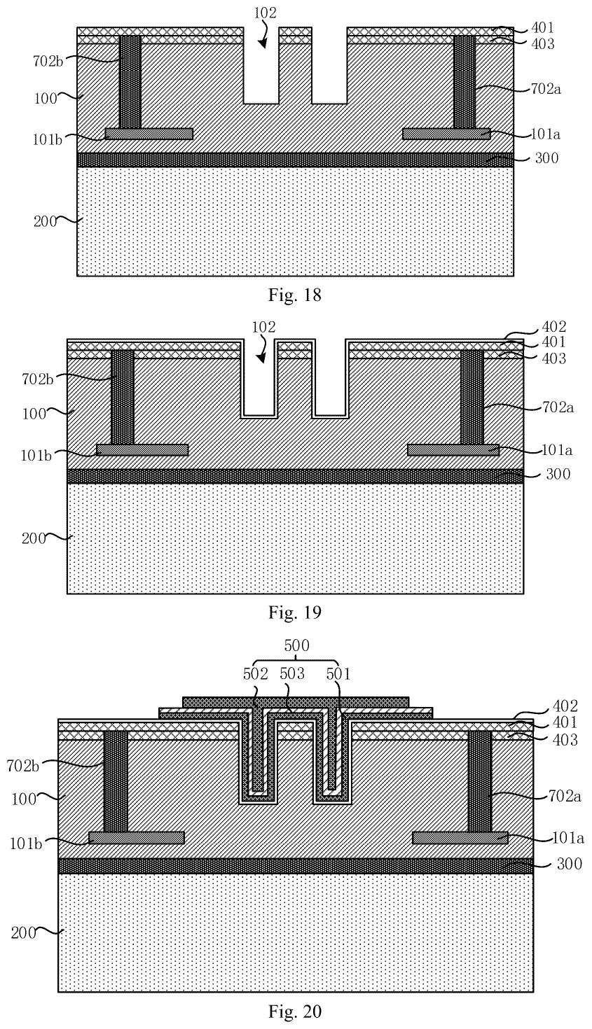

As shown in FIG. 18, a first mask layer 401 is formed on the second mask layer 403. The first mask layer 401 completely covers the second mask layer 403. Subsequently, a local etching process is carried out, which proceeds through the first mask layer 401 and the second mask layer 403 into the second semiconductor substrate 100, forming at least one deep trench 102 extending through the first mask layer 401, the second mask layer 403 and a partial thickness of the underlying second semiconductor substrate 100.

As shown in FIG. 19, an isolation layer 402 is conformally formed over the first mask layer 401. The isolation layer 402 further extends into and lines the deep trench 102.

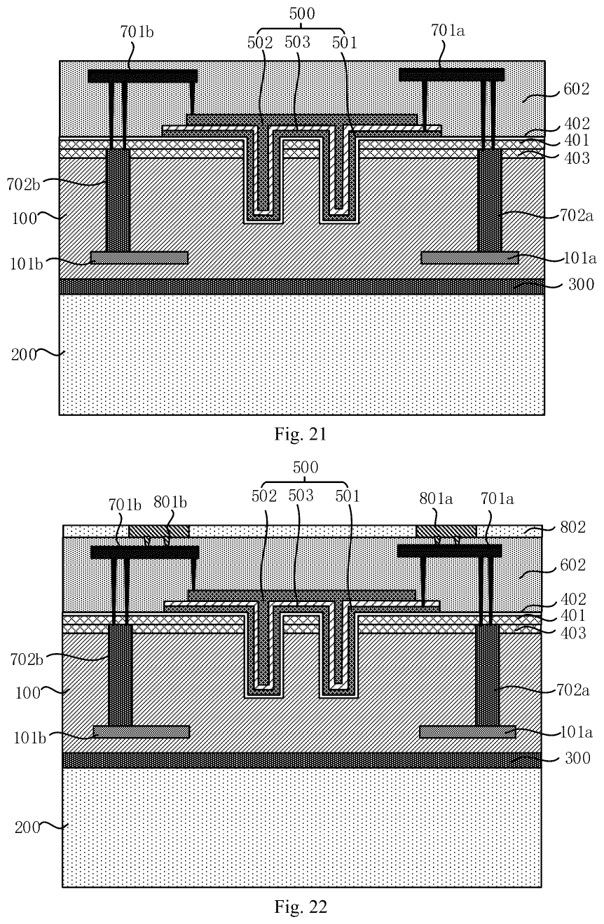

As shown in FIG. 20, a first conductive layer 501, a dielectric material layer 503 and a second conductive layer 502 are successively formed on a surface portion of the isolation layer 402. The first conductive layer 501, the second conductive layer 502 and the dielectric material layer 503 all extend into and together fill the deep trench 102, thus forming a DTC structure 500. In this embodiment, the first conductive layer 501 and the dielectric material layer 503 both cover the surface portion of the isolation layer 402, and the second conductive layer 502 covers a surface portion of the dielectric material layer 503. The DTC structure 500 is electrically isolated from the second semiconductor substrate 100 by the isolation layer 402.

As shown in FIG. 21, a second dielectric sub-layer 602 is formed over the isolation layer 402 and the DTC structure 500. The second dielectric sub-layer 602 covers the isolation layer 402 and the DTC structure 500. A first interconnect structure 701a and a second interconnect structure 701b are formed in the second dielectric sub-layer 602. The first interconnect structure 701a resides on top of the first plug structure 702a and is electrically connected to the second end of the first plug structure 702a and the first conductive layer 501 in the DTC structure 500. The second interconnect structure 701b resides on top of the second plug structure 702b and is electrically connected to the second end of the second plug structure 702b and the second conductive layer 502 in the DTC structure 500.

As shown in FIG. 22, a first dielectric bond layer 802 is formed on the second dielectric sub-layer 602. The first dielectric bond layer 802 covers the second dielectric sub-layer 602. A first metal bond layer is then formed in the first dielectric bond layer 802, which includes a first metal bond sub-layer 801a and a second metal bond sub-layer 801b. The first metal bond sub-layer 801a also extends into the second dielectric sub-layer 602 and is electrically connected to the first interconnect structure 701a. The second metal bond sub-layer 801b also extends into the second dielectric sub-layer 602 and is electrically connected to the second interconnect structure 701b. Surfaces of the first metal bond sub-layer 801a and the second metal bond sub-layer 801b are at least partially exposed outside the first dielectric bond layer 802. The first dielectric bond layer 802 and the first metal bond layer together constitute a first hybrid bonding structure.

Afterwards, similar to the step of FIG. 11, a first semiconductor substrate 100 is processed to form a second dielectric bond layer 803 on its front side.

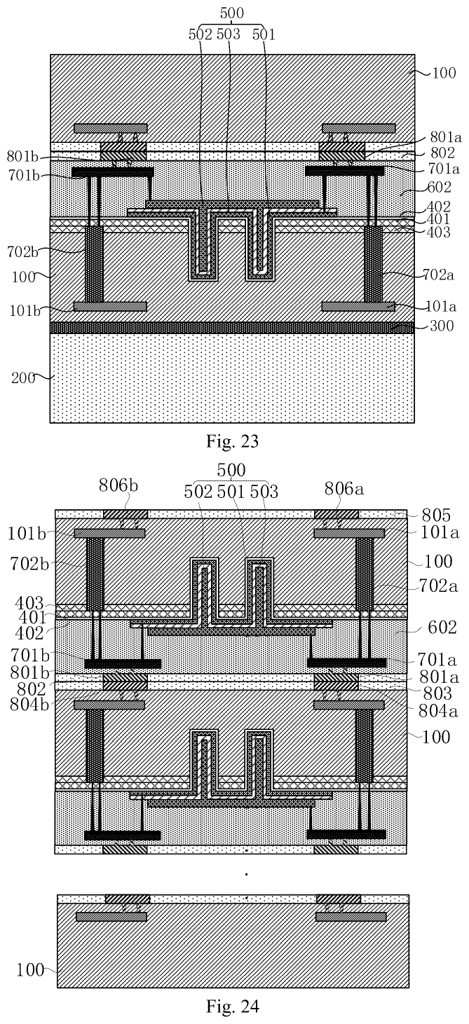

As shown in FIG. 23, the front side of the first semiconductor substrate 100 is bonded to the backside of the second semiconductor substrate 100.

As a result of the above steps, the two semiconductor substrates 100 are stacked together.

Next, as shown in FIG. 24, with the first semiconductor substrate 100 of FIG. 23 being now taken as a new second semiconductor substrate 100 and another semiconductor substrate 100 as a new first semiconductor substrate 100, the above steps are repeated to further stack the other semiconductor substrate 100. In this way, new first semiconductor substrates 100 can be successively stacked on respective second semiconductor substrates 100. In each adjacent pair of semiconductor substrates 100, the stacking of the first semiconductor substrate 100 on the second semiconductor substrate 100 involves: first forming a first dielectric layer, plug structures, a DTC structure 500 and a first hybrid bonding structure on the backside of the second semiconductor substrate 100; then forming a second hybrid bonding structure on the front side of the first semiconductor substrate 100; and finally bonding the front side of the first semiconductor substrate 100 to the backside of the second semiconductor substrate 100 through the first and second hybrid bonding structures. As such, a desired number of semiconductor substrates 100 can be stacked together.

After all the semiconductor substrates 100 are stacked together, the support substrate 200 may be debonded and then removed together with the temporary bond layer 300. After that, a second dielectric layer 805 may be formed on the initial second semiconductor substrate 100, and a first external connection terminal 806a and a second external connection terminal 806b in the second dielectric layer 805. The first external connection terminal 806a and the second external connection terminal 806b may also extend into the initial second semiconductor substrate 100 and be electrically connected to the first power metal layer 101a and the second power metal layer 101b therein, respectively. The first external connection terminal 806a and the second external connection terminal 806b serve for external connection.

### Example 3

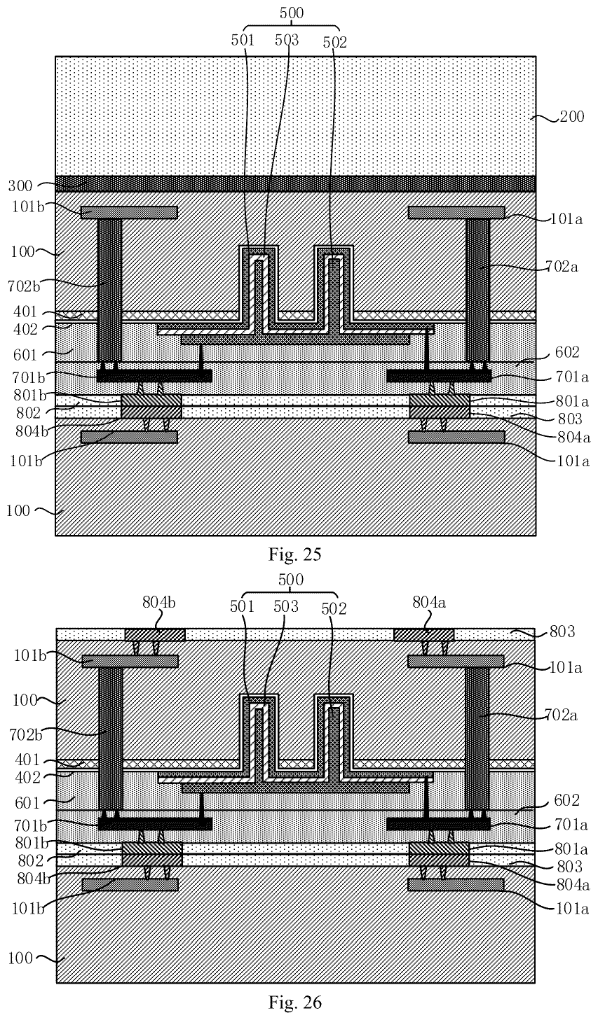

FIGS. 25 to 28 are schematic diagrams showing structures resulting from respective steps in a method of fabricating a semiconductor device according to a third embodiment of the present invention. As shown in FIGS. 25 to 28, it differs from the first embodiment in that each second semiconductor substrate 100 is stacked on a corresponding first semiconductor substrate 100.

Specifically, the steps of FIGS. 2 to 10 are carried out to form a first dielectric layer, plug structures, a DTC structure 500 and a first hybrid bonding structure on the backside of a second semiconductor substrate 100. The step of FIG. 11 is then performed to form a second hybrid bonding structure on the front side of a first semiconductor substrate 100.

The steps for forming the first dielectric layer, the plug structures, the DTC structure 500, the first hybrid bonding structure and the second hybrid bonding structure have been described in detail above in connection with the first embodiment and, therefore, need not be described in further detail herein.

As shown in FIG. 25, the backside of the second semiconductor substrate 100 is bonded to the front side of the first semiconductor substrate 100 through the first hybrid bonding structure on the backside of the second semiconductor substrate 100 and the second hybrid bonding structure on the front side of the first semiconductor substrate 100.

As a result of the above steps, the two semiconductor substrates 100 are stacked together.

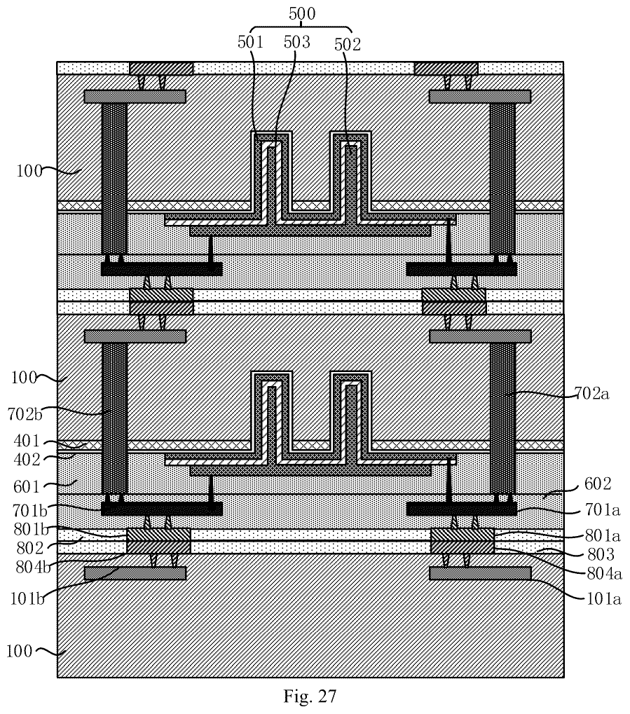

As shown in FIG. 26, the support substrate 200 is debonded and then removed together with the temporary bond layer 300. With the second semiconductor substrate 100 of FIG. 26 being now taken as a new first semiconductor substrate 100, a second hybrid bonding structure is formed on the front side of this first semiconductor substrate 100 (i.e., the second semiconductor substrate 100 of FIG. 26).

A new semiconductor substrate 100 is taken as a second semiconductor substrate 100, and the above steps are repeated. That is, the steps of FIGS. 2 to 10 are carried out to form a first dielectric layer, plug structures, a DTC structure 500 and a first hybrid bonding structure on the backside of the second semiconductor substrate 100. As shown in FIG. 27, the backside of the second semiconductor substrate 100 is bonded to the front side of the first semiconductor substrate 100 through the first hybrid bonding structure on the backside of the second semiconductor substrate 100 and the second hybrid bonding structure on the front side of the first semiconductor substrate 100, achieving the stacking of the new semiconductor substrate 100.

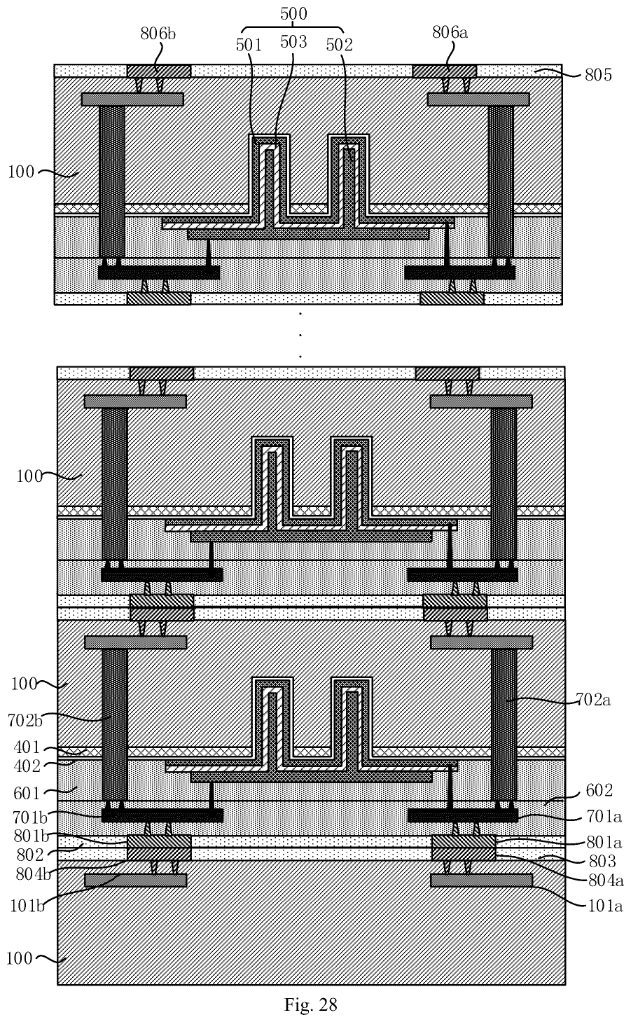

As shown in FIG. 28, new second semiconductor substrates 100 can be successively stacked on respective first semiconductor substrates 100 in the same way as described above. In each adjacent pair of semiconductor substrates 100, the stacking of the semiconductor substrates 100 involves: forming a first dielectric layer, plug structures, a DTC structure 500 and a first hybrid bonding structure on the backside of the second semiconductor substrate 100; then forming a second hybrid bonding structure of the front side of the first semiconductor substrate 100; and finally bonding the backside of the second semiconductor substrate 100 to the front side of the first semiconductor substrate 100 through the first and second hybrid bonding structures. As such, a desired number of semiconductor substrates 100 can be stacked together.

After all the semiconductor substrates 100 are stacked together, a second dielectric layer 805 may be formed on the front side of the last second semiconductor substrate 100, and a first external connection terminal 806a and a second external connection terminal 806b in the second dielectric layer 805. The first external connection terminal 806a and the second external connection terminal 806b may also extend into the last second semiconductor substrate 100 and be electrically connected to the first power metal layer 101a and the second power metal layer 101b therein, respectively. The first external connection terminal 806a and the second external connection terminal 806b serve for external connection.

In summary, the present invention provides a semiconductor device including external connection terminals and at least two stacked semiconductor substrates. In each adjacent pair of semiconductor substrates, a first semiconductor substrate is bonded to a backside of a second semiconductor substrate. The external connection terminals are electrically connected to an adjacent second semiconductor substrate. In each adjacent pair of semiconductor substrates, the two semiconductor substrates are be electrically connected to each other by plug structures contained in a first dielectric layer between the two semiconductor substrates. When the external connection terminals are connected to an external power source, the latter can supply power to each semiconductor substrate through a power transmission path constructed of the plug structures. At least some of the first dielectric layer(s) each contain a DTC structure electrically connected to second ends of the plug structures in the specific first dielectric layer. During propagation of an electrical signal through the plug structures, it passes through the DTC structure before arriving at the downstream semiconductor substrate. The DTC structure can filter out any parasitic inductance that the plug structures introduce, facilitating powering of the downstream semiconductor substrate. With this arrangement, the power transmission path has lower impedance, and reduced voltage drops occur along the path, allowing more chips/wafers to be stacked together. The present invention also provides a method of fabricating the semiconductor device.

It is to be noted that the embodiments disclosed herein are described in a progressive manner, with the description of each embodiment focusing on its differences from others. Cross reference can be made between the embodiments for their common or similar features. Since the system embodiments correspond to the method embodiments, they are described relatively briefly, and reference can be made to the method embodiments for more details thereof.

It is also to be noted that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent alternatives and modifications made to the foregoing embodiments based on the substantive disclosure of the invention without departing from the scope thereof fall within the scope.

Further, it is to be understood that, as used herein, the terms “first”, “second”, “third” and the like are only meant to distinguish various components, elements, steps, etc. from each other and are not intended to indicate logical or sequential orderings thereof, unless otherwise indicated or specified.

It is also to be recognized that the terminology used herein is for the purpose of describing particular embodiments only, and is not intended to limit the scope of the present invention. It must be noted that, as used herein and in the appended claims, the singular forms “a” and “an” include the plural reference unless the context clearly dictates otherwise. Thus, for example, a reference to “a step” or “a means” is a reference to one or more steps or means and may include sub-steps and sub-means. All conjunctions used are to be understood in the most inclusive sense possible. Thus, the term “or” should be understood as having the definition of a logical “or” rather than that of a logical “exclusive or” unless the context clearly necessitates otherwise. Further, implementation of the method and/or device according to the embodiments of the present invention may involve performing selected tasks manually, automatically, or a combination thereof.

1. A semiconductor device, comprising external connection terminals and at least two stacked semiconductor substrates, each of the semiconductor substrates comprising power metal layers, wherein in each adjacent pair of semiconductor substrates, a first semiconductor substrate is bonded to a backside of a second semiconductor substrate, and there is a first dielectric layer between the first semiconductor substrate and the second semiconductor substrate; wherein the external connection terminals are adjacent to a second semiconductor substrate and electrically connected to the power metal layers therein;
each first dielectric layer contains plug structures, which also extend into the corresponding second semiconductor substrate, and first ends and second ends of the plug structures are electrically connected to the power metal layers in the corresponding first semiconductor substrate and the corresponding second semiconductor substrate, respectively; and
at least some of the first dielectric layer(s) each contain a deep trench capacitor structure, which also extends into the corresponding second semiconductor substrate and is electrically connected to the second ends of the corresponding plug structures.

2. The semiconductor device of claim 1, wherein the power metal layers in each semiconductor substrate include a first power metal layer and a second power metal layer, and the plug structures in each first dielectric layer include a first plug structure and a second plug structure, and
wherein a first end and a second end of the first plug structure are electrically connected to the corresponding first power metal layers, and a first end and a second end of the second plug structure are electrically connected to the corresponding second power metal layers.

3. The semiconductor device of claim 2, wherein the deep trench capacitor structure comprises a first conductive layer and a second conductive layer, which are alternately stacked on top of each other, wherein each first conductive layer is separated from each adjacent second conductive layer by a dielectric material layer; and
wherein each first conductive layer is electrically connected to the second end of the corresponding first plug structure, and each second conductive layer is electrically connected to the second end of the corresponding second plug structure.

4. The semiconductor device of claim 3, wherein each first dielectric layer further contains interconnect structures including a first interconnect structure and a second interconnect structure,
the first interconnect structure electrically connecting the corresponding first conductive layer to the second end of the corresponding first plug structure, the second interconnect structure electrically connecting the corresponding second conductive layer to the second end of the corresponding second plug structure.

5. The semiconductor device of claim 1, wherein each first dielectric layer comprises a first mask layer and a first dielectric sub-layer, which are stacked sequentially in the order on the backside of the corresponding second semiconductor substrate, wherein:
the plug structures are formed in the first dielectric sub-layer and extend through the first mask layer into the corresponding second semiconductor substrate; and
the deep trench capacitor structure is formed between the first dielectric sub-layer and the first mask layer and extends through the first mask layer into the corresponding second semiconductor substrate.

6. The semiconductor device of claim 1, wherein each first dielectric layer comprises a second mask layer, a first mask layer and a second dielectric sub-layer, which are stacked sequentially in the order on the backside of the corresponding second semiconductor substrate, wherein:
the plug structures are formed in the second mask layer and extend through the second mask layer into the corresponding second semiconductor substrate; and
the deep trench capacitor structure is formed between the second dielectric sub-layer and the first mask layer and extends through the first mask layer and the second mask layer into the corresponding second semiconductor substrate.

7. The semiconductor device of claim 1, wherein between each first dielectric layer and the corresponding first semiconductor substrate, there is also a hybrid bonding structure comprising a first dielectric bond layer, a second dielectric bond layer, a first metal bond layer and a second metal bond layer,
the first dielectric bond layer attached to a surface of the specific first dielectric layer, the second dielectric bond layer attached to a front side of the first semiconductor substrate, the first metal bond layer embedded in the first dielectric bond layer and electrically connected to the plug structures in the specific first dielectric layer, the second metal bond layer embedded in the second dielectric bond layer and electrically connected to the power metal layers in the first semiconductor substrate,
a surface of the first metal bond layer at least partially exposed outside the first dielectric bond layer, a surface of the second metal bond layer at least partially exposed outside the second dielectric bond layer, surfaces of the first dielectric bond layer and the second dielectric bond layer attached to each other, the surfaces of the first metal bond layer and the second metal bond layer attached to each other, the first semiconductor substrate and the second semiconductor substrate bonded to each other through the hybrid bonding structure.

8. The semiconductor device of claim 1, wherein one of the semiconductor substrates is a logic substrate, and each of the other semiconductor substrate(s) is a device substrate, wherein the logic substrate is an outermost one of the semiconductor substrates.

9. The semiconductor device of claim 4, wherein the first interconnect structure and the second interconnect structure each comprise stacked multiple metal layers and a conductive plug connecting adjacent metal layers, and wherein the first interconnect structure and the second interconnect structure comprise conductive materials.

10. The semiconductor device of claim 2, wherein the external connection terminals comprise a first external connection terminal and a second external connection terminal, the first external connection terminal is electrically connected to the corresponding first power metal layer, and the second external connection terminal is electrically connected to the corresponding second power metal layer.

11. A method of fabricating a semiconductor device, comprising:
providing at least two semiconductor substrates each comprising power metal layers; and
stacking all the semiconductor substrates together and forming external connection terminals, wherein in each adjacent pair of semiconductor substrates, a first semiconductor substrate is bonded to a backside of a second semiconductor substrate, and there is a first dielectric layer between the first semiconductor substrate and the second semiconductor substrate; the external connection terminals are adjacent to a second semiconductor substrate and electrically connected to the power metal layers therein; each first dielectric layer contains plug structures, which also extend into the corresponding second semiconductor substrate, and first ends and second ends of the plug structures are electrically connected to the power metal layers in the corresponding first semiconductor substrate and the corresponding second semiconductor substrate, respectively; and at least some of the first dielectric layer(s) each contain a deep trench capacitor structure, which also extends into the corresponding second semiconductor substrate and is electrically connected to the second ends of the corresponding plug structures.

12. The method of claim 11, wherein all the semiconductor substrates are stacked together in such a manner that, in each adjacent pair of semiconductor substrates, the first semiconductor substrate is stacked on the second semiconductor substrate by: forming the first dielectric layer, the plug structures, the deep trench capacitor structure and a first hybrid bonding structure on the backside of the second semiconductor substrate and a second hybrid bonding structure on the front side of the first semiconductor substrate; and then bonding the front side of the first semiconductor substrate to the backside of the second semiconductor substrate through the first and second hybrid bonding structures, and wherein
after all the semiconductor substrates are stacked together, the external connection terminals are formed on the front side of the initial second semiconductor substrate.

13. The method of claim 11, wherein all the semiconductor substrates are stacked together in such a manner that, in each adjacent pair of semiconductor substrates, the second semiconductor substrate is stacked on the first semiconductor substrate by: forming the first dielectric layer, the plug structures, the deep trench capacitor structure and a first hybrid bonding structure on the backside of the second semiconductor substrate and a second hybrid bonding structure on the front side of the first semiconductor substrate; and then bonding the second semiconductor substrate to the first semiconductor substrate through the first and second hybrid bonding structures, and wherein
after all the semiconductor substrates are stacked together, the external connection terminals are formed on the front side of the last second semiconductor substrate.

14. The method of claim 12, wherein the formation of the first dielectric layer, the plug structures and the deep trench capacitor structure on the backside of the semiconductor substrate comprises:
forming a first mask layer on the backside of the semiconductor substrate and performing a local etching process, which proceeds through the first mask layer and a partial thickness of the semiconductor substrate, forming at least one deep trench;
forming the deep trench capacitor structure on the first mask layer, which covers a surface portion of the first mask layer and extends into the deep trench;
forming a first dielectric sub-layer over the first mask layer and the deep trench capacitor structure and performing a local etching process, which proceeds the first dielectric sub-layer, the first mask layer and a partial thickness of the semiconductor substrate, forming via holes exposing the power metal layers;
filling a conductive material into the via holes, forming the plug structures; and
forming a second dielectric sub-layer on the first dielectric sub-layer, the first mask layer, the first dielectric sub-layer and the second dielectric sub-layer together constitute the first dielectric layer.

15. The method of claim 12, wherein the formation of the first dielectric layer, the plug structures and the deep trench capacitor structure on the backside of the semiconductor substrate comprises:
forming a second mask layer on the backside of the semiconductor substrate and performing a local etching process, which proceeds through the second mask layer and a partial thickness of the semiconductor substrate, forming via holes exposing the power metal layers;
filling a conductive material into the via holes, forming the plug structures;
forming a first mask layer on the second mask layer and performing a local etching process, which proceeds the first mask layer, the second mask layer and a partial thickness of the semiconductor substrate, forming at least one deep trench;
forming the deep trench capacitor structure on the first mask layer, which covers a surface portion of the first mask layer and extends into the deep trench; and
forming a second dielectric sub-layer over the first mask layer and the deep trench capacitor structure, the first mask layer, the second mask layer and the second dielectric sub-layer together constitute the first dielectric layer.

16. The method of claim 12, wherein during the formation of the first dielectric layer, interconnect structures are also formed in the first dielectric layer, which are electrically connected to the second ends of the plug structures and the deep trench capacitor structure.

17. The method of claim 16, wherein the formation of the first hybrid bonding structure on the first dielectric layer comprises:
forming a first dielectric bond layer on the first dielectric layer; and
forming a first metal bond layer in the first dielectric bond layer, which is electrically connected to the plug structures by the interconnect structures, and a surface of which is at least partially exposed outside the first dielectric bond layer, and wherein the formation of the second hybrid bonding structure on the front side of the semiconductor substrate comprises:
forming a second dielectric bond layer on the front side of the semiconductor substrate; and
forming a second metal bond layer in the second dielectric bond layer, which is electrically connected to the power metal layers in the semiconductor substrate, and a surface of which is at least partially exposed outside the second dielectric bond layer.

18. The method of claim 13, wherein the formation of the first dielectric layer, the plug structures and the deep trench capacitor structure on the backside of the semiconductor substrate comprises:
forming a first mask layer on the backside of the semiconductor substrate and performing a local etching process, which proceeds through the first mask layer and a partial thickness of the semiconductor substrate, forming at least one deep trench;
forming the deep trench capacitor structure on the first mask layer, which covers a surface portion of the first mask layer and extends into the deep trench;
forming a first dielectric sub-layer over the first mask layer and the deep trench capacitor structure and performing a local etching process, which proceeds the first dielectric sub-layer, the first mask layer and a partial thickness of the semiconductor substrate, forming via holes exposing the power metal layers;
filling a conductive material into the via holes, forming the plug structures; and
forming a second dielectric sub-layer on the first dielectric sub-layer, the first mask layer, the first dielectric sub-layer and the second dielectric sub-layer together constitute the first dielectric layer.

19. The method of claim 13, wherein the formation of the first dielectric layer, the plug structures and the deep trench capacitor structure on the backside of the semiconductor substrate comprises:
forming a second mask layer on the backside of the semiconductor substrate and performing a local etching process, which proceeds through the second mask layer and a partial thickness of the semiconductor substrate, forming via holes exposing the power metal layers;
filling a conductive material into the via holes, forming the plug structures;
forming a first mask layer on the second mask layer and performing a local etching process, which proceeds the first mask layer, the second mask layer and a partial thickness of the semiconductor substrate, forming at least one deep trench;
forming the deep trench capacitor structure on the first mask layer, which covers a surface portion of the first mask layer and extends into the deep trench; and
forming a second dielectric sub-layer over the first mask layer and the deep trench capacitor structure, the first mask layer, the second mask layer and the second dielectric sub-layer together constitute the first dielectric layer.

20. The method of claim 13, wherein the external connection terminals comprise a first external connection terminal and a second external connection terminal, the first external connection terminal is electrically connected to the corresponding first power metal layer, and the second external connection terminal is electrically connected to the corresponding second power metal layer.
